(19) United States
(12) Patent Application Publication
(10) Pub. No.: US 2008/0003788 A1
(43) Pub. Date: Jan. 3, 2008

(54) METHOD OF MANUFACTURING SEMICONDUCTOR DEVICE

(75) Inventors: Chul Young Ham, Guri-si (KR); Noh Yeal Kwak, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/617,188

(22) Filed: Dec. 28, 2006

(30) Foreign Application Priority Data
Jun. 30, 2006 (KR) 2006-60538

(51) Int. Cl. H01L 21/425

(52) U.S. Cl. 438/530

(57) ABSTRACT

A method of manufacturing a semiconductor device includes the steps of forming a gate for a high voltage transistor on a semiconductor substrate, forming a Double Doped Drain (DDD) junction in the semiconductor substrate by means of an ion implantation process employing a DDD mask, and removing point defects, which have occurred in the DDD junction during the ion implantation process, by means of a Defect Recovery Anneal (DRA) process.

### CROSS-REFERENCES TO RELATED APPLICATIONS

The present application claims priority to Korean patent application number 10-2006-60538, filed on Jun. 30, 2006, which is incorporated by reference in its entirety.

### BACKGROUND OF THE INVENTION

The present invention relates to semiconductor devices and, more particularly, to a method of manufacturing a semiconductor device, in which the method can improve point defects occurring in a Double Doped Drain (DDD) junction for a high voltage transistor by means of a thermal treatment process.

As the level of integration of semiconductor devices increases, a channel length decreases. Thus, a semiconductor fabrication technique, such as a Lightly Doped Drain (LDD) or a DDD, has been proposed. The LDD and DDD are classified depending on the control of the concentration of a source and drain in order to prevent “hot carriers” in occurring in the semiconductor devices.

In the case of a flash memory device, a DDD junction for a high voltage transistor is formed. In this case, ion implantation is performed at a relatively low dose. Such ion implantation may cause point defects of silicon (Si). The point defects results in an increase in the change of dopant depletion with respect to peripheral factors, and also causes Transient Enhanced Diffusion (TED) at the time of high-temperature thermal for ion activation. In particular, in the case of the source and drain junction, the TED is weakened by the point defects, so that the leakage current is generated.

### BRIEF SUMMARY OF THE INVENTION

The present invention is directed to a method of manufacturing a semiconductor device, in which the method can eliminate point defects of silicon, which occur due to ion implantation when a DDD junction for a high voltage transistor is formed, thus improving electrical characteristics of the device.

In one embodiment of the present invention, a method of manufacturing a semiconductor device includes forming a gate for a high voltage transistor on a semiconductor substrate; forming a DDD junction in the semiconductor substrate by means of an ion implantation process employing a DDD mask; and removing point defects, which have occurred in the DDD junction during the ion implantation process, by means of a Defect Recovery Anneal (DRA) process.

### BRIEF DESCRIPTION OF THE DRAWINGS

FIGS. 1 to 3 are cross-sectional views illustrating a method of manufacturing a semiconductor device according to an embodiment of the present invention.

### DESCRIPTION OF SPECIFIC EMBODIMENTS

Embodiments in accordance with the present invention will be described with reference to the accompanying drawings.

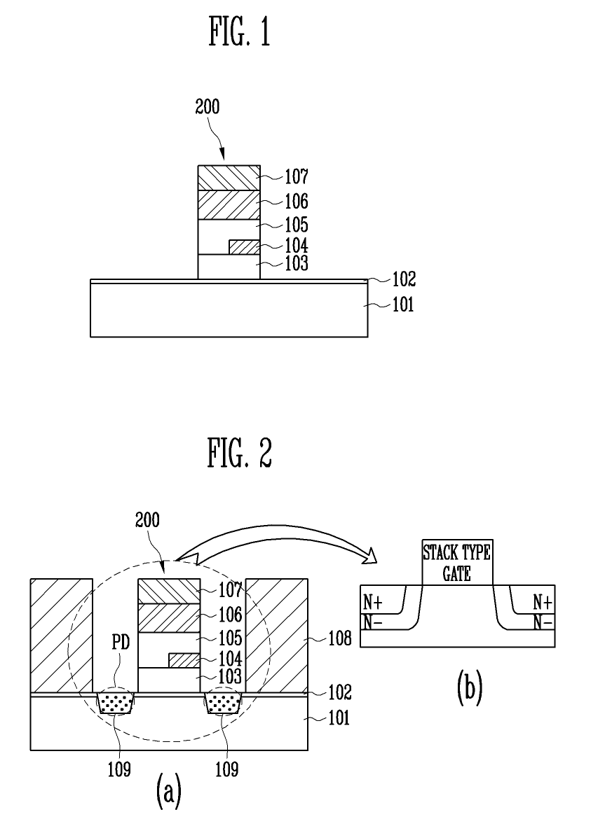

FIGS. 1 to 3 are cross-sectional views illustrating a method of manufacturing a semiconductor device according to an embodiment of the present invention. This drawing illustrates a high voltage transistor portion of a flash memory device.

Referring to FIG. 1, in order to form a triple isolated well junction in a P type semiconductor substrate 101, triple N (TN)-well ion implantation and P-well ion implantation are performed on the semiconductor substrate 101.

Ion implantation using BF₂ having a relatively high mass as a dopant is performed in order to form a channel junction in a surface channel. At the time of ion implantation, energy may be set in the range of approximately 5 KeV to approximately 50 KeV and a dose may range from approximately 1E11 ions/cm² to approximately 1E14 ions/cm². Furthermore, in order to maximize ion collisions, ion implantation is performed at a tilt of approximately 3 degrees to approximately 45 degrees.

Threshold voltage (Vt) control ion implantation is performed on the semiconductor substrate 101 in which a high voltage NMOS transistor will be formed. The threshold voltage (Vt) control ion implantation process employs B11 (or BF₂) having a low mass as a dopant, and can thus minimize the occurrence of ion implantation defects. The threshold voltage control ion implantation process can be performed at a tilt of approximately 1 degrees to approximately 50 degrees in order to prevent channeling of a dopant by using energy ranging from approximately 5 KeV to approximately 50 KeV and a dose ranging from approximately 1E11 ions/cm² to approximately 1E14 ions/cm².

Shallow trench isolation (STI) is formed by an etch process employing a Self-Aligned STI (SASTI) method, thus dividing an active region and a STI region.

An insulating layer 102, a first polysilicon layer 103, a dielectric layer 104, a second polysilicon layer 105, a conductive layer 106 and a hard mask layer 107 are sequentially formed over a semiconductor substrate 101. Gates for a cell and a transistor are formed by means of a gate etch process. The gate illustrated in FIG. 1 is a gate 200 for a high voltage transistor.

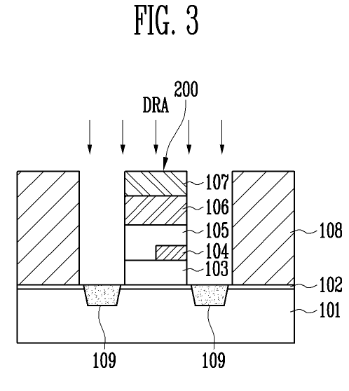

Referring to FIG. 2A, a DDD mask 108 is formed. DDD ion implantation is implemented to form DDD junctions 109. At the time of ion implantation, energy may be set in the range of approximately 5 KeV to approximately 100 KeV, and a dose may be set in the range of approximately 1E11 ions/cm² to approximately 1E14 ions/cm². In some embodiments of the present invention, in order to prevent an anisotropic junction from being formed due to a shadow phenomenon of the DDD mask 108, ion implantation is carried out vertically. In this case, point defects (PD) may occur in the DDD junctions 109 due to the ion implantation. A detailed cross-section of a portion in which the DDD junction 109 is formed is illustrated in FIG. 2B.

Referring to FIG. 2B, a stack type gate structure 200 is formed on the semiconductor substrate 101. DDD junctions 109 are formed in the semiconductor substrate 101 at both sides of the gate 200. An N+region within an N-region becomes a source and drain region.

Referring to FIG. 3, a DRA process can be performed on the entire surface of the resulting structure in order to remove the PD (refer to FIG. 2A). The DRA process can be performed in a temperature range of approximately 800 degrees Celsius to approximately 820 degrees Celsius for approximately 0 minutes to approximately 300 minutes while rapidly raising a ramp-up temperature in the range of approximately 20 degrees Celsius/sec to approximately 250 degrees Celsius/sec. In this case, ‘0 minutes’ means that a spike is applied. The DRA process can be performed under nitrogen (N₂) atmosphere in order to prevent the oxidization of the silicon semiconductor substrate.

If the DRA process is performed at the lower portion of the temperature range as described above, point defects within the semiconductor substrate 101, which have been generated at the time of ion implantation, can be removed. At the time of the DRA process, there is almost no movement of an impurity, and only point defects of the semiconductor substrate 101 are removed. Thereafter, a high-temperature (e.g., approximately 820 degrees Celsius) thermal treatment process is performed in order to activate the ion of the DDD junction 109.

As described above, in accordance with a method of manufacturing a semiconductor device according to an embodiment of the present invention, point defects occurring at the time of DDD ion implantation of a high voltage NMOS transistor can be removed through DRA. Accordingly, the occurrence of TED can be prevented, a threshold voltage can be stabilized, and the leakage current can be decreased.

The above embodiments of the present invention are illustrative and not limitative. Various alternatives and equivalents are possible. Other additions, subtractions, or modifications are obvious in view of the present disclosure and are intended to fall within the scope of the appended claims.

What is claimed is:

1. A method of manufacturing a semiconductor device, the method comprising:
forming a gate for a high voltage transistor on a semiconductor substrate;
forming a Double Doped Drain (DDD) junction in the semiconductor substrate by using an ion implantation process employing a DDD mask; and
removing point defects formed in the DDD junction during the ion implantation process using a Defect Recovery Anneal (DRA) process.

2. The method of claim 1, wherein the ion implantation process is performed by using energy of approximately 5 KeV to approximately 50 KeV and by using a dose of approximately 1 E11 ions/cm² to approximately 1E14 ions/cm².

3. The method of claim 1, wherein the ion implantation process is performed at a vertical collision tilt angle.

4. The method of claim 3, wherein the vertical collision tilt angle is approximately 3 degrees to approximately 45 degrees.

5. The method of claim 1, wherein the DRA process is performed in a temperature range of approximately 800 degrees Celsius to approximately 820 degrees Celsius using a nitrogen (N₂) gas in a state where a ramp-up temperature is set in the range of approximately 20 degrees Celsius/sec to approximately 250 degrees Celsius/sec, and time is set in the range of approximately 0 minutes to approximately 300 minutes.

6. The method of claim 1, further comprising performing a high-temperature thermal treatment process of activating the ion of the DDD junction, after the DRA process.
